(19) United States
(12) Patent Application Publication
(10) Pub. No.: US 2023/0288677 A1
(43) Pub. Date: Sep. 14, 2023

(54) CAMERA MODULE

(71) Applicant: SAMSUNG ELECTRO-MECHANICS CO., LTD., Suwon-si (KR)

(72) Inventor: Ik Sun LEE, Suwon-si (KR)

(73) Assignee: SAMSUNG ELECTRO-MECHANICS CO., LTD., Suwon-si (KR)

(21) Appl. No.: 18/095,640

(22) Filed: Jan. 11, 2023

(30) Foreign Application Priority Data
Mar. 11, 2022 (KR) 10-2022-0030376

(51) Int. Cl. G02B 13/00; G03B 17/17; G03B 5/00

(52) U.S. Cl. CPC G02B 13/0065; G03B 17/17; G03B 5/00; G03B 2205/0023; G03B 2205/0069

(57) ABSTRACT

A camera module includes a housing having an internal space, a lens module disposed in the internal space and including a plurality of lenses, a reflective module in front of the lens module and including a reflective member and a holder provided with the reflective member mounted thereon, a driving unit moving the lens module in the optical axis direction or rotating the reflective module in a direction, perpendicular to the optical axis direction, as a rotation axis, and a cover coupled to the housing. The driving unit includes a plurality of magnets, and a plurality of coils disposed in the housing to face the plurality of magnets, respectively, and the plurality of coils are disposed to be closer to a first surface of the cover facing a bottom surface of the housing than to the bottom surface of the housing in a direction, perpendicular to the optical axis direction.

### CROSS-REFERENCE TO RELATED APPLICATIONS

This application claims the benefit under 35 USC § 119(a) of Korean Patent Application No. 10-2022-0030376, filed on Mar. 11, 2022, in the Korean Intellectual Property Office, the entire disclosure of which is incorporated herein by reference for all purposes.

### BACKGROUND

### 1. Field

The following description relates to a camera module.

### 2. Description of Related Art

Camera modules are implemented in portable electronic devices including, but not limited to, smartphones, and as portable electronic devices are manufactured to have a thin thickness according to market demand, the miniaturization of camera modules is also desirous.

On the other hand, apart from the desire to miniaturize camera modules, performance improvement of camera modules is also desirous. However, there is a limit to the amount the size of the camera module may be reduced since functions or operations such as an autofocusing (AF) function or operation, an optical image stabilization (OIS) function or operation and the like may be added to the camera module.

For example, the camera module may have a problem in that it is difficult to reduce the size of the camera module despite demand for miniaturization, and therefore, there is a limit in reducing the thickness of portable electronic devices.

To prevent this problem, camera modules having a structure including a plurality of lenses arranged in the longitudinal or width direction rather than in the thickness direction of the portable electronic device and a reflective member that changes the path or direction of light has been proposed.

Additionally, to improve the performance of the camera operations of the portable electronic device, a plurality of cameras have been mounted or a touch pen function has been added to the portable electronic device, so that the components in which the magnetic field is generated are disposed adjacently to each other. Thus, there is a problem in which magnetic field interference occurs.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In a general aspect, a camera module includes a housing configured to have an internal space; a lens module disposed in the internal space, and comprising a plurality of lenses arranged in an optical axis direction; a reflective module, disposed in front of the lens module, and comprising a reflective member and a holder provided with the reflective member mounted thereon; a driving unit configured to move the lens module in the optical axis direction or configured to rotate the reflective module in a direction, perpendicular to the optical axis direction, as a rotation axis; and a cover coupled to the housing, wherein the driving unit comprises a plurality of magnets, and a plurality of coils disposed in the housing to face the plurality of magnets, respectively, and wherein the plurality of coils are disposed to be closer to a first surface of the cover facing a bottom surface of the housing than to the bottom surface of the housing in a direction, perpendicular to the optical axis direction.

The camera module may further include a plurality of position sensors configured to detect positions of the lens module and positions of the reflective module, wherein the plurality of position sensors are disposed to be closer to the bottom surface of the housing than to the first surface of the cover facing the bottom surface of the housing in the direction, perpendicular to the optical axis direction.

The driving unit may include a first driving unit including a first magnet and a first coil, and configured to rotate the reflective module with respect to the housing, by implementing a first axis, perpendicular to the optical axis, as a rotation axis; a second driving unit including a second magnet and a second coil, and configured to rotate the reflective module with respect to the housing, by implementing a second axis, perpendicular to the optical axis, as a rotation axis; and a third driving unit including a third magnet and a third coil, and configured to move the lens module in the optical axis direction with respect to the housing.

The first magnet and the second magnet may have a length in the first axis direction, and the third magnet may have a length in the optical axis direction.

The third magnet may be disposed to be closer to the cover, on the first surface of the cover facing the bottom surface of the housing, than the bottom surface of the housing, in a direction, perpendicular to the optical axis direction.

The plurality of position sensors may include a first position sensor configured to face the first magnet; a second position sensor configured to face the second magnet; and a third position sensor configured to face the lens module.

A surface of the first magnet that faces the first coil may be provided as a first polarity, a neutral region and a second polarity sequentially in the optical axis direction.

The first position sensor may be configured to face the neutral region.

A surface of the second magnet that faces the second coil may be provided as a first polarity, a first neutral region, a second polarity, a second neutral region, and a first polarity sequentially in the first axis direction.

The second position sensor may be configured to face the second neutral region.

The cover may be formed of a metal material that shields electromagnetic waves.

At least one of the housing and the reflective module may include a first pulling magnet on surfaces that face each other in the optical axis direction, such that an attractive force acts between the housing and the reflective module in the optical axis direction.

The first pulling magnet may be polarized in a longitudinal direction and a width direction.

At least one of the housing and the lens module may include a second pulling magnet on surfaces that face each other in a direction, perpendicular to the optical axis direction, such that an attractive force acts between the housing and the lens module in a direction, perpendicular to the optical axis direction.

The second pulling magnet may be polarized in a longitudinal direction and a width direction.

In a general aspect, a camera module includes a housing having an open upper portion; a lens module and a reflective module disposed in the housing, and configured to have at least one magnet mounted on a side thereof; and a substrate disposed on a side surface of the housing and configured to have a plurality of coils mounted on a surface that faces an inside of the housing, wherein the reflective module is configured to rotate with a first axis and a second axis, perpendicular to an optical axis direction, as rotation axes, and wherein the plurality of magnets and the plurality of coils are disposed to face each other in a position higher than a point where the first axis and the second axis intersect.

Other features and aspects will be apparent from the following detailed description, the drawings, and the claims.

### BRIEF DESCRIPTION OF DRAWINGS

FIG. 1 is a perspective view of an example portable electronic device equipped with a camera module, in accordance with one or more embodiments.

FIG. 2 is a schematic perspective view of an example camera module, in accordance with one or more embodiments.

FIG. 3A is a cross-sectional view taken along line I-I′ of FIG. 2.

FIG. 3B is a cross-sectional view taken along line II-II′ of FIG. 2.

FIG. 4 is an exploded perspective view of an example camera module, in accordance with one or more embodiments.

FIG. 5 is a perspective view of a housing of an example camera module, in accordance with one or more embodiments.

FIG. 6 is a perspective view in which a reflective module and a lens module are coupled to a housing of an example camera module, in accordance with one or more embodiments.

FIG. 7 is a perspective view in which a driving coil and a board on which an image sensor is mounted are coupled to a housing of an example camera module, in accordance with one or more embodiments.

FIG. 8 is a side view of a housing in an example in which a substrate illustrating the arrangement relationship of a driving unit of an example camera module, in accordance with one or more embodiments, has been removed.

FIG. 9 is an exploded perspective view of a rotating plate and a holder of an example camera module, in accordance with one or more embodiments.

FIG. 10 is an exploded perspective view of a housing and a holder of an example camera module, in accordance with one or more embodiments.

FIG. 11A, FIG. 11B, and FIG. 11C are views illustrating an example in which a reflective module of an example camera module rotates about a first axis (X-axis) as a rotation axis, in accordance with one or more embodiments.

FIG. 12A, FIG. 12B, and FIG. 12C are views illustrating an example in which a reflective module of an example camera module rotates about a second axis (Y-axis) as a rotation axis, in accordance with one or more embodiments.

FIGS. 13A and 13B are conceptual diagrams of a magnetic field according to a magnetization form of a pulling magnet, in accordance with one or more embodiments.

FIG. 14 is a view illustrating a portion in which an attractive force is formed between a reflective module and a housing of an example camera module, in accordance with one or more embodiments.

FIG. 15 is a diagram illustrating a portion in which an attractive force is formed between a lens module and a housing of an example camera module, in accordance with one or more embodiments.

Throughout the drawings and the detailed description, the same reference numerals may refer to the same, or like, elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known, after an understanding of the disclosure of this application, may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. Likewise, expressions, for example, “between” and “immediately between” and “adjacent to” and “immediately adjacent to” may also be construed as described in the foregoing.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof. The use of the term “may” herein with respect to an example or embodiment (for example, as to what an example or embodiment may include or implement) means that at least one example or embodiment exists where such a feature is included or implemented, while all examples are not limited thereto.

Unless otherwise defined, all terms, including technical and scientific terms, used herein have the same meaning as commonly understood by one of ordinary skill in the art to which this disclosure pertains consistent with and after an understanding of the present disclosure. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

One or more examples may provide a camera module in which magnetic flux leakage may be reduced.

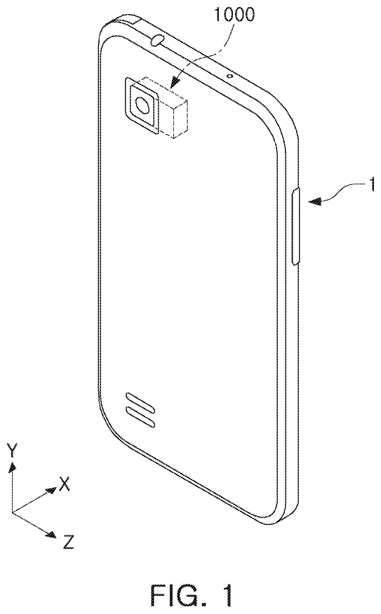

FIG. 1 is a perspective view of an example portable electronic device equipped with a camera module according to an example.

Referring to FIG. 1, a camera module 1000 according to an example may be mounted on a portable electronic device 1. Although a smartphone is illustrated as an example of the portable electronic device 1 in the drawing, the portable electronic device 1 is not limited thereto, portable electronic devices such as, but not limited to, tablet personal computers (PCs) and laptops are not limited to specific products.

As illustrated in FIG. 1, the portable electronic device 1 may be equipped with a camera module 1000 to photograph a subject.

According to an example, the camera module 1000 may include a plurality of lenses. The plurality of lenses refers to the thickness direction of the portable electronic device 1 (the X-axis direction based on the drawing, and the portable electronic device 1 may be disposed in a direction perpendicular to the direction from the front surface to the rear surface (or the opposite direction). In detail, the optical axis (Z-axis) of the plurality of lenses may be formed in a direction perpendicular to the thickness direction of the portable electronic device 1, and specifically, may be formed in the width direction or the longitudinal direction of the portable electronic device 1.

According to this structure, even when the camera module 1000 has an autofocusing function or operation, an optical zoom function or operation, an optical image stabilization function or operation and the like, the thickness of the portable electronic device 1 may not increase, and therefore, the portable electronic device 1 may have a relatively thin form factor.

According to an example, the camera module 1000 may include at least one of the aforementioned autofocusing function (AF function), optical zoom function, and an optical image stabilization function (OIS function).

In order for the camera module 1000 to implement these functions, various parts must be provided, compared to the general camera module, the size has to be increased, as the size of the camera module 1000 increases, the size of the portable electronic device 1 on which the camera module 1000 is mounted also increases.

For example, the camera module 1000 may include a plurality of lens groups to implement an optical zoom function, and when a plurality of lens groups are disposed in the thickness direction of the portable electronic device, the thickness of the portable electronic device also increases according to the number of lens groups. For example, if the thickness of the portable electronic device is not increased, the number of lens groups cannot be sufficiently secured, such that the optical zoom performance is weakened.

In addition, in order for the camera module 1000 to implement an autofocusing function, an optical image stabilization function, and the like, an actuator that moves the plurality of lens groups in the optical axis direction (Z-axis direction) or in a direction perpendicular to the optical axis (X-axis and Y-axis directions) should be provided. If a plurality of lens groups are disposed in the thickness direction of the portable electronic device, since the actuator that moves the lens group should also be provided in the thickness direction of the portable electronic device, the thickness of portable electronic devices increases.

However, in an example, in the camera module 1000, a plurality of lenses may be disposed in a direction perpendicular to the thickness direction (X-axis direction) of the portable electronic device 1, and the optical axis (Z-axis) of the plurality of lenses is formed in a direction perpendicular to the thickness direction (X-axis direction) of the portable electronic device 1. Therefore, even when the camera module 1000 having an autofocusing function, an optical zoom function, and an optical image stabilization function is implemented in the portable electronic device 1, since the thickness of the portable electronic device 1 does not increase, the portable electronic device 1 may be relatively thin.

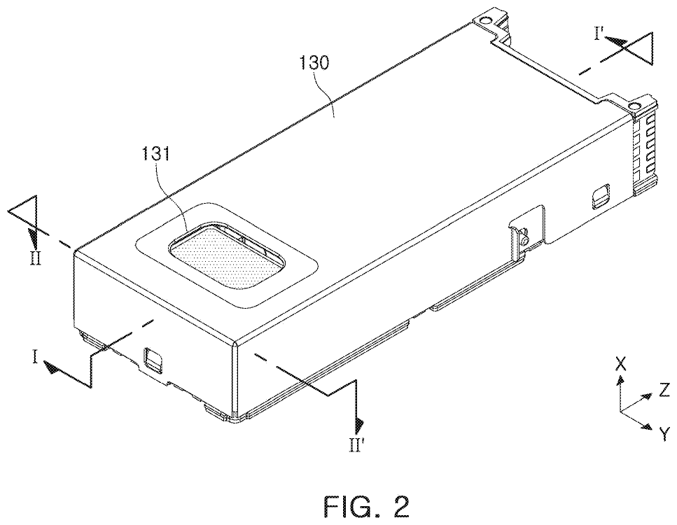

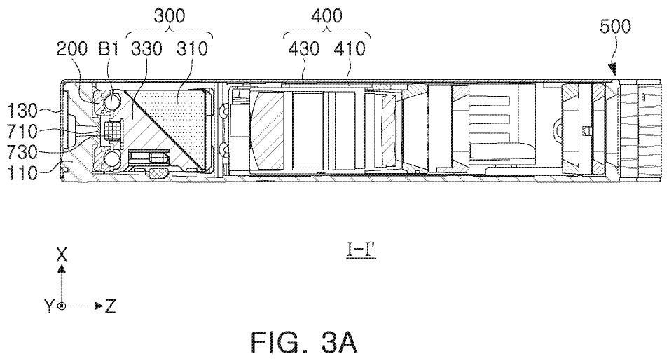

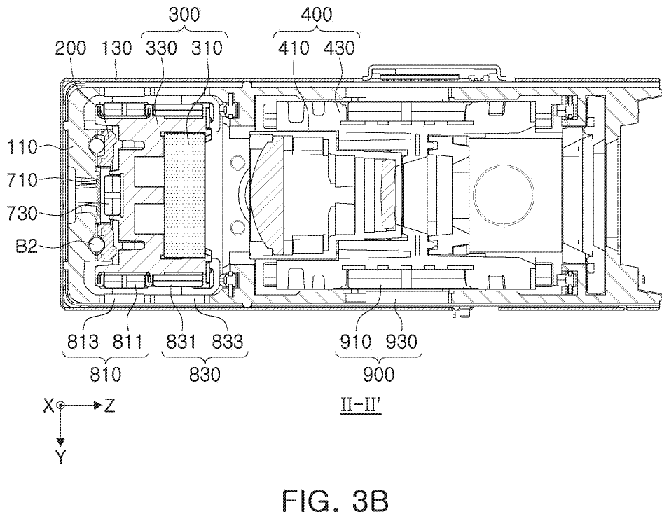

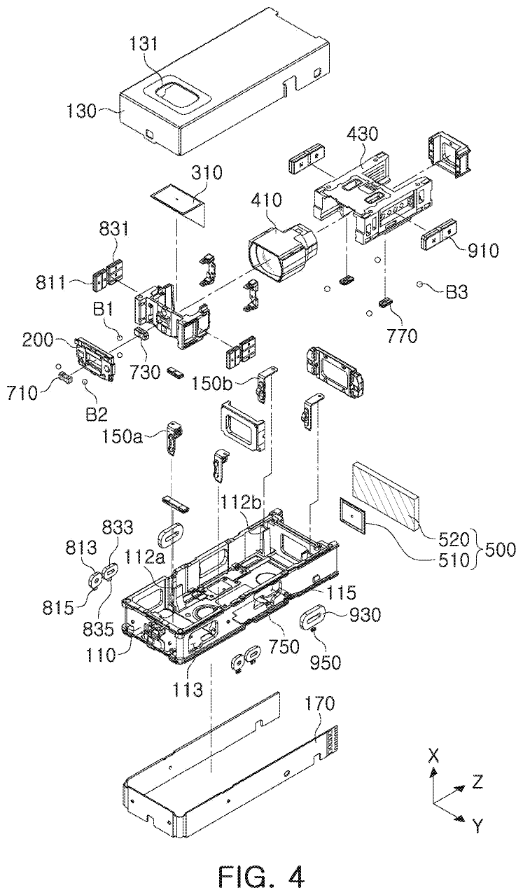

FIG. 2 is a schematic perspective view of an example camera module, in accordance with one or more embodiments, FIG. 3A is a cross-sectional view taken along II-I′ of FIG. 2, FIG. 3B is a cross-sectional view taken along II-II′ of FIG. 2, and FIG. 4 is an exploded perspective view of a camera module, in accordance with one or more embodiments.

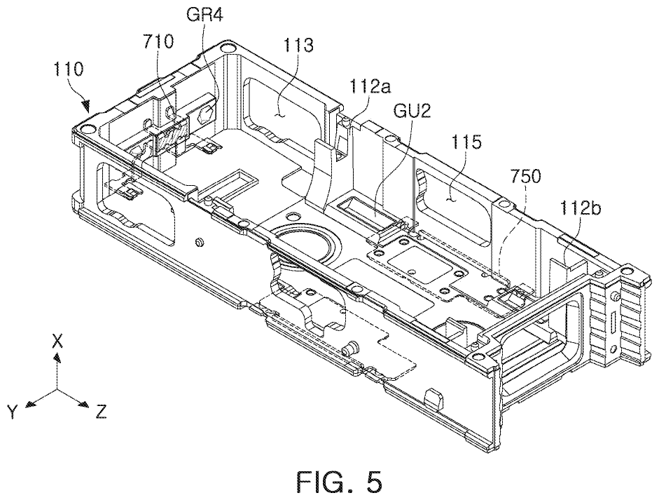

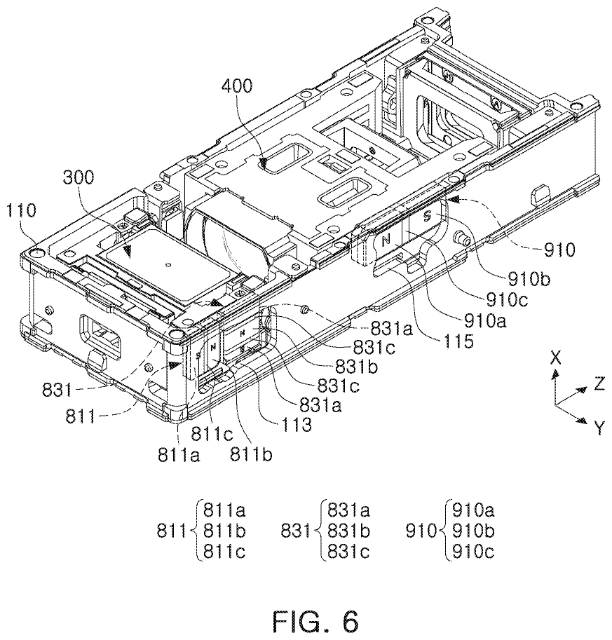

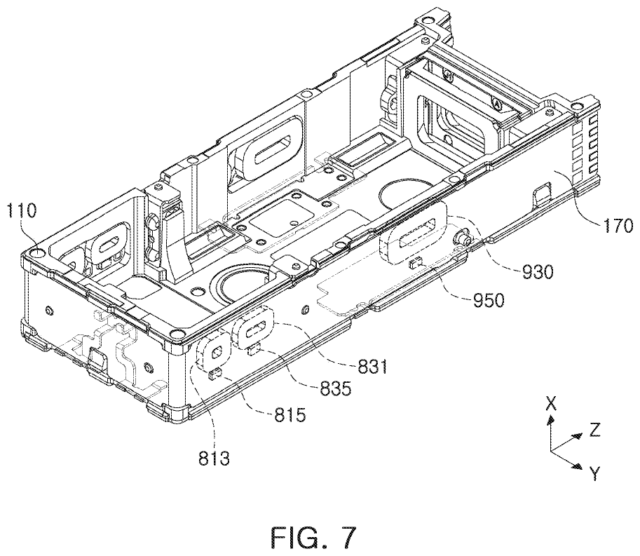

FIG. 5 is a perspective view of a housing of a camera module, in accordance with one or more embodiments, FIG. 6 is a perspective view in which a reflective module and a lens module are coupled to the housing of the camera module, in accordance with one or more embodiments, and FIG. 7 is a perspective view in which a driving coil and a board on which an image sensor is mounted are combined in a housing of a camera module, in accordance with one or more embodiments.

The camera module 1000, in accordance with one or more embodiments, may include a housing 110, a reflective module 300, a lens module 400, an image sensor module 500, and a cover 130.

The housing 110 may be a part formed of a material that is easy to mold, for example, a plastic material.

As illustrated in FIG. 5, the housing 110 may be in the shape of a box with an open upper portion, and may be in the form of having a length in the optical axis direction (Z-axis direction) or may extend in the optical axis direction. The housing 110 may have an internal space, and the above-described components may be disposed in the internal space of the housing 110 or may be directly or indirectly mounted on the side surface of the housing 110.

For example, in the internal space of the housing 110, the reflective module 300, the lens module 400, and the image sensor module 500 may be sequentially disposed from a first side to a second side. When described based on the propagation path of light, the reflective module 300 may be disposed at the frontmost side of the housing 110, and the image sensor module 500 may be disposed at the rearmost side of the housing 110. As another example, the reflective module 300 and the lens module 400 may be disposed in the internal space of the housing 110, and the image sensor module 500 may be provided in a form attached to the side of the housing 110 from the outside of the housing 110.

On the other hand, as another example, the reflective module 300 and the lens module 400 may be respectively disposed in separate housings. In this example, the housing in which the reflective module 300 is disposed and the housing in which the lens module 400 is disposed may be coupled to each other. Additionally, the housing in which the reflective module 300 is disposed and the housing in which the lens module 400 is disposed may have a structure in which at least a portion of portions coupled to each other is open such that the light reflected from the reflective module 300 passes through the lens module 400.

The cover 130 may be coupled to the open upper portion of the housing 110 to cover the internal space of the housing 110. The cover 130 may protect components disposed in the internal space of the housing 110, including a reflective module 300, a lens module 400 and an image sensor module 500, from external impact.

Additionally, the cover 130 may shield the components within the housing 110 from electromagnetic waves. Accordingly, in a non-limited example, the cover 130 may be formed of a metal material. The cover 130 is formed of a metal material having an electromagnetic wave shielding function. Electromagnetic waves generated from the camera module 1000 according to an example may be prevented from affecting other electronic components provided in the portable electronic device 1, and conversely, electromagnetic waves generated from other electronic components included in the portable electronic device 1 may be prevented from affecting the camera module 1000 according to an example.

On the other hand, the cover 130 faces the outside of the portable electronic device 1, and the housing 110 may be disposed to face the inside of the portable electronic device 1. Accordingly, the cover 130 may include an opening 131 through which light is incident. Light is incident through the opening 131, and the progress path or direction of the light may be changed by the reflective module 300.

For example, the path of the light incident through the opening 131 of the cover 130 may be changed to be directed toward the lens module 400 based on the reflective module 300. Specifically, in the example of the light incident in the thickness direction (X-axis direction) of the portable electronic device 1, the traveling path may be changed to approximately coincide with the optical axis direction (Z-axis direction) of the plurality of lenses by the reflective module 300.

The reflective module 300 may include a reflective member 310 and a holder 330 on which the reflective member 310 is mounted.

The reflective member 310 is configured to change the propagation path of light, and for example, the reflective member 310 may be provided as a mirror or prism that reflects light.

In the camera module 1000 according to an example, a handshake optical image stabilization function may be implemented by rotating the reflective member 310. Specifically, the holder 330 on which the reflective member 310 is mounted moves in a direction (X-axis and Y-axis direction) perpendicular to the optical axis direction (Z-axis direction), or may be configured to rotate by a predetermined angle with axes (X and Y axes) perpendicular to the optical axis (Z-axis) as rotation axes. Hereinafter, axes perpendicular to the optical axis (Z-axis) are referred to as a first axis (X-axis) and a second axis (Y-axis), respectively, and a direction perpendicular to the optical axis direction (Z-axis direction) is referred to as a first axis direction (X-axis direction) and a second axis direction (Y-axis direction), respectively. Therefore, in the one or more examples, the configuration for moving the reflective module 300 in the first axis or the second axis direction (X-axis or Y-axis direction) perpendicular to the optical axis (Z-axis) may be a handshake correction unit.

The lens module 400 may include a plurality of lenses through which the light reflected from the reflective module 300 passes, a lens barrel 410 provided with a plurality of lenses, and a carrier 430 on which the lens barrel 410 is mounted.

In the camera module 1000 according to an example, an automatic focus adjustment operation may be implemented by moving the carrier 430. Specifically, the carrier 430 on which the lens barrel 410 is mounted may be configured to move in the optical axis direction (Z-axis direction). Therefore, in the one or more examples, the configuration to move the lens module 400 in the optical axis direction (Z-axis direction) may be an autofocus adjustment unit.

The image sensor module 500 may include an image sensor 510 that converts light passing through a plurality of lenses into an electrical signal, and a printed circuit board (PCB) 520 on which the image sensor 510 is mounted. Additionally, the image sensor module 500 may further include an optical filter (not illustrated) to filter light incident on the image sensor 510 through the lens module 400. In a non-limited example, the optical filter may be an infrared cut filter.

On the other hand, the housing 110 may include a protruding wall 112 that partitions a space in which the reflective module 300, the lens module 400, and the image sensor module 500 are disposed.

Specifically, the protruding wall 112 may be formed in a shape protruding from both inner walls of the housing 110, and having a length in the optical axis direction (Z-axis direction) toward the internal space of the housing 110, and may include a first protruding wall 112a and a second protruding wall 112b that are spaced apart in the optical axis direction (Z-axis direction).

In summary, the internal space of the housing 110 is divided into a space in which the reflective module 300 is disposed and a space in which the lens module 400 is disposed by the first protruding wall 112a, and a space in which the lens module 400 is disposed and a space in which the image sensor module 500 is disposed may be divided by the second protruding wall 112b.

A hook-shaped stopper 150 may be fitted to the protruding wall 112. The stopper 150 may be fitted to the protruding wall 112 such that the hook portion is caught on the upper portion of the protruding wall 112. Specifically, the first stopper 150a may be fitted to the first protruding wall 112a, and a second stopper 150b may be fitted to the second protruding wall 112b.

The first stopper 150a may limit the rotation range of the holder 330 while supporting the holder 330. A predetermined space may be provided between the holder 330 and the first stopper 150a such that the holder 330 may be rotated.

The second stopper 150b may limit the movement range of the carrier 430 while supporting the carrier 430. The carrier 430 may move in the optical axis direction (Z-axis direction) between the first stopper 150a and the second stopper 150b. In this example, a certain space may be provided between the carrier 430 and the first stopper 150a or the second stopper 150b such that the carrier 430 may move.

Additionally, a buffer member (not illustrated) may be attached to both surfaces of the stopper 150. The buffer member may be formed of an elastically deformable material, thereby reducing the impact and noise generated when the reflective module 300, the lens module 400, and the image sensor module 500 collide with the stopper 150.

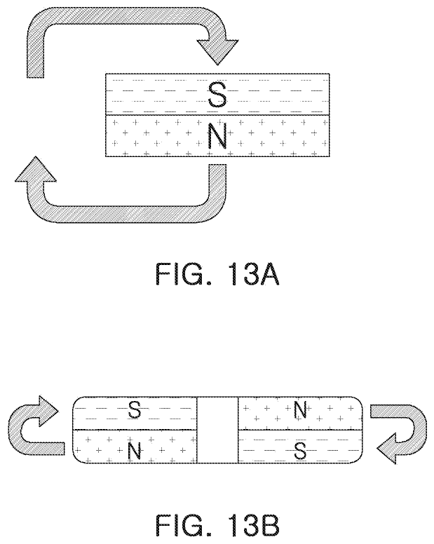

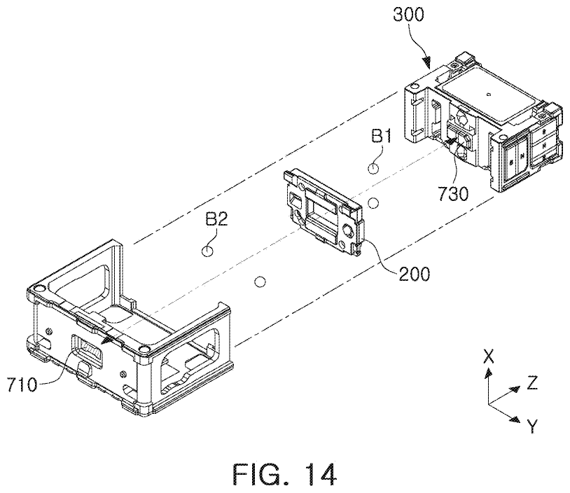

FIGS. 13A and 13B are conceptual views of a magnetic field according to a magnetization form of a pulling magnet, and FIG. 14 is a view illustrating a portion in which an attractive force is formed between a housing of a camera module and a reflective module, in accordance with one or more embodiments.

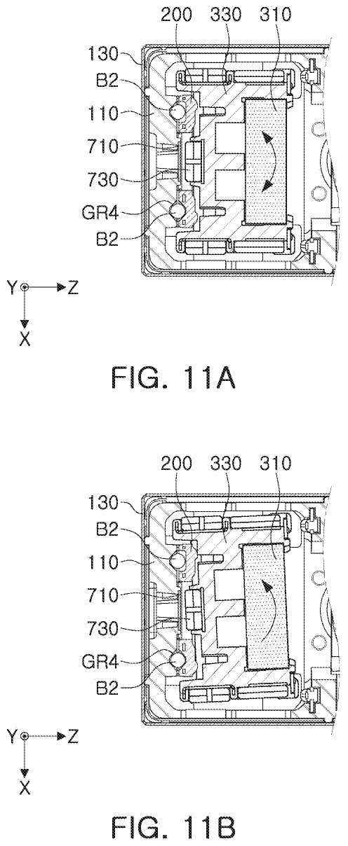

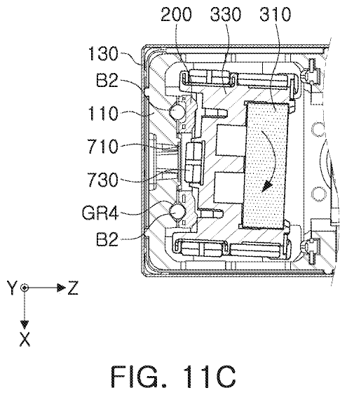

The reflective module 300 may be supported on the inner surface of the housing 110 in an example in which it is disposed in the internal space of the housing 110. For example, as illustrated in FIG. 11, the reflective module 300 may be pulled toward the inner surface of the housing 110 in the optical axis direction (Z-axis direction).

Accordingly, magnetic materials may be disposed on surfaces facing each other in the optical axis direction (Z-axis direction) of the housing 110 and the reflective module 300. Specifically, a first magnetic body is disposed in the housing 110, a second magnetic material may be disposed in the holder 330 of the reflective module 300, and at least one of the first magnetic material and the second magnetic material may be a pulling magnet.

For example, the first magnetic material disposed in the housing 110 is a pulling yoke (hereinafter, a first pulling yoke) 710, and the second magnetic material disposed in the holder 330 may be a pulling magnet (hereinafter, referred to as a first pulling magnet) 730.

The first pulling yoke 710 and the first pulling magnet 730 may be disposed to face each other in the optical axis direction (Z-axis direction) to generate an attractive force in the optical axis direction (Z-axis direction). Accordingly, the reflective module 300 may be pulled toward the inner surface of the housing 110 in the optical axis direction (Z-axis direction).

On the contrary, the first magnetic body disposed in the housing 110 is the first pulling magnet 730, the second magnetic body disposed in the holder 330 may be the first pulling yoke 710, and an example in which both the first magnetic body and the second magnetic body disposed in the housing 110 and the holder 330 are the first pulling magnet 730 is also possible.

In a non-limiting example, the first pulling yoke 710 may be provided in the form of a thin plate.

On the other hand, since the first pulling magnet 730 is disposed adjacent to the inner surface of the housing 110 such that the reflective module 300 is supported on the inner surface of the housing 110, when the magnetic field is formed over a wide area, a portion may leak to the outside of the camera module 1000. Accordingly, the first pulling magnet 730 according to an example may be provided in a form polarized in the longitudinal direction and the width direction.

Referring to FIG. 13, the magnet polarized in the longitudinal and width directions as illustrated in FIG. 13(b) may be located in a relatively narrow area than the magnet polarized in either direction, for example, the width direction, as illustrated in FIG. 13(a). A magnetic field may be formed.

In the example of the camera module 1000 according to an example, since the first pulling magnet 730 may be provided in a polarized shape in the longitudinal direction and the width direction, magnetic field leakage may be significantly reduced.

Additionally, the reflective module 300 may be pulled in the optical axis direction (Z-axis direction) when disposed in the internal space of the housing 110, and may be pulled toward the inner surface of the housing 110 in the first axial direction (X-axis direction).

Accordingly, magnetic materials may be disposed on surfaces of the housing 110 and the reflective module 300 facing each other in the first axis direction (X-axis direction). For example, a magnetic material such as the aforementioned pulling yoke or pulling magnet may be disposed in the holder 330 of the housing 110 and the reflective module 300.

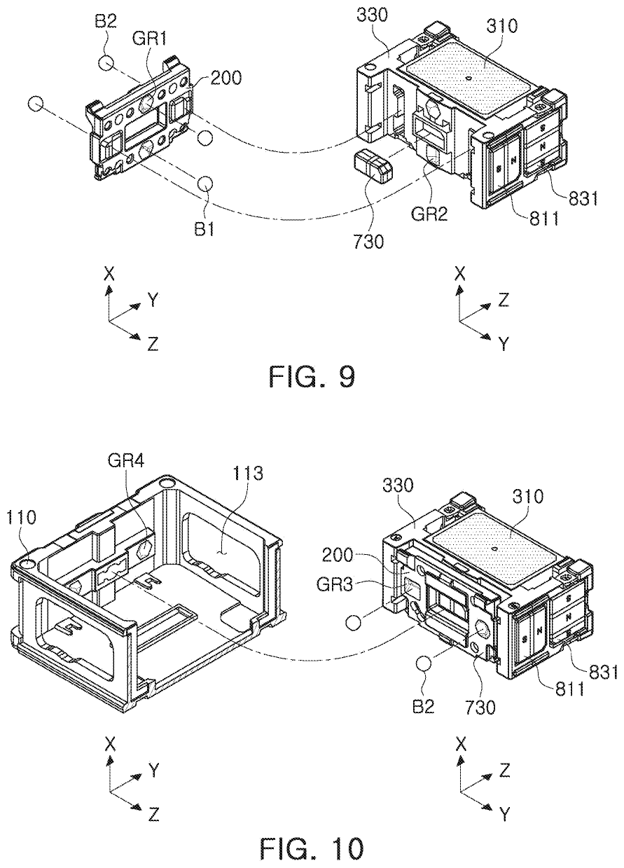

FIG. 9 is an exploded perspective view of the rotating plate and holder of the camera module according to an example, and FIG. 10 is an exploded perspective view of the housing and holder of the camera module, in accordance with one or more embodiments.

Referring to FIGS. 9 and 10, the rotating plate 200 may be disposed between the reflective module 300 (310, 330) and the inner surface of the housing 110. Even when the rotating plate 200 is present between the reflective module 300 and the housing 110, the rotating plate 200 may be provided with a through-hole 210 such that an attractive force may act in the optical axis direction (Z-axis direction) between the reflective module 300 and the inner surface of the housing 110, and the first pulling yoke 710 and the first pulling magnet 730 may directly face each other through the through-hole 210.

The rotating plate 200 may be formed by the attractive force acting between the first pulling yoke 710 disposed in the housing 110 and the first pulling magnet 730 disposed in the holder 330, and may be pulled toward the inner surface of the housing 110 in the optical axis direction (Z-axis direction) together with the reflective module 300.

Ball members may be disposed between the rotating plate 200 and the reflective module 300, and between the rotating plate 200 and the housing 110. Specifically, the first ball members B1 may be disposed between the rotating plate 200 and the holder 330 of the reflective module 300, and second ball members B2 may be disposed between the rotating plate 200 and the housing 110.

The first ball members B1 include a plurality of ball members spaced apart along a first axis (X-axis) perpendicular to the optical axis (Z-axis), and the second ball members B2 may include a plurality of ball members spaced apart along a second axis (Y-axis) perpendicular to the optical axis (Z-axis) and the first axis (X-axis).

The rotating plate 200 and the reflective module 300 may have receiving grooves in which the first ball members B1 is accommodated, respectively, on surfaces facing each other in the optical axis direction (Z-axis direction). For example, the rotating plate 200 is provided with a first accommodating groove GR1 on a surface facing the reflective module 300 in the optical axis direction (Z-axis direction), the reflective module 300 may be provided with a second receiving groove GR2 on a surface facing the rotating plate 200 and the optical axis direction (Z-axis direction), and the first receiving groove GR1 and the second receiving groove GR2 may include a plurality of receiving grooves spaced apart along a first axis (X-axis) perpendicular to the optical axis (Z-axis).

The first ball members (B1) may be disposed between the first receiving groove (GR1) and the second receiving groove (GR2), and the first pulling yoke 710 and the first pulling magnet 730 by the attractive force between the first accommodating groove (G1) and the second accommodating groove (G2) may be stably arranged without departing.

The rotating plate 200 and the housing 110 may have accommodating grooves in which the second ball members B2 are accommodated, respectively, on surfaces facing each other in the optical axis direction (Z-axis direction). For example, the rotating plate 200 is provided with a third receiving groove (GR3) on the inner surface of the housing 110 and the surface facing the optical axis direction (Z-axis direction), the inner surface of the housing 110 may be provided with a fourth receiving groove GR4 on a surface facing the rotating plate 200 and the optical axis direction (Z-axis direction), and the third receiving groove GR3 and the fourth receiving groove GR4 may include a plurality of receiving grooves spaced apart along the second axis (Y-axis) perpendicular to the optical axis (Z-axis) and the first axis (X-axis).

The second ball members (B2) may be disposed between the third receiving groove (GR3) and the fourth receiving groove (GR4), and the first pulling yoke 710 and the first pulling magnet 730 by the attractive force between the third accommodating groove (GR3) and the fourth accommodating groove (GR4) may be arranged stably without departing.

According to an example, the camera module 1000 may correct hand shake during a photographing process by rotating the reflective module 300. For example, in an example in which camera shake occurs during an image capture process, the hand shake may be corrected in such a manner that a relative displacement corresponding to the shaking caused by the hand shake is given to the reflective module 300.

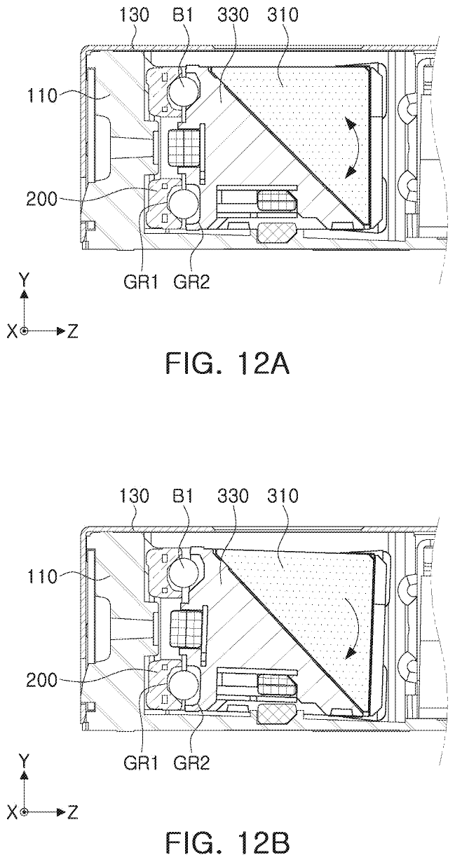

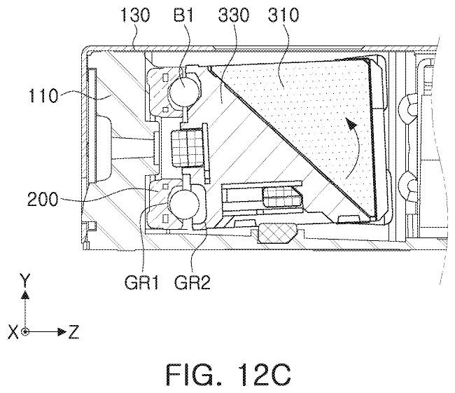

FIGS. 11A to 110 are views illustrating an example in which a reflective module of a camera module rotates about a first axis (X-axis) as a rotation axis, in accordance with one or more embodiments, and FIGS. 12A to 12C are diagrams illustrating an example in which a reflective module of a camera module rotates about a second axis (Y-axis) as a rotation axis, in accordance with one or more embodiments.

The reflective module 300 may be rotated using a first axis (X-axis) and a second axis (Y-axis) perpendicular to the optical axis (Z-axis) as rotation axes. The reflective module 300 may be relatively rotated with respect to the rotation plate 200 using the first axis (X-axis) as the rotation axis. Additionally, the reflective module 300 may be rotated relative to the housing 110 together with the rotation plate 200 using the second axis (Y-axis) as a rotation axis.

Referring to FIG. 9, a first ball member B1 may be disposed between the rotating plate 200 and the reflective module 300, and the first ball member B1 may include a plurality of ball members spaced apart from each other in the first axial direction (X-axis direction). Accordingly, the reflective module 300 may be rotated about the first axis (X-axis) as a rotation axis while being supported by the first ball member B1 spaced apart from each other in the first axis direction (X-axis direction). At the same time, the reflective module 300 may be limited in relative rotation with respect to the rotating plate 200 using the second axis (Y-axis) as the rotation axis.

Referring to FIG. 10, a second ball member B2 may be disposed between the housing 110 and the rotating plate 200, and the second ball member B2 may include a plurality of ball members spaced apart from each other in the second axis direction (Y-axis direction). Accordingly, the rotating plate 200 may be rotated with the second axis (Y-axis) as the rotation axis while being supported by the second ball members B2 spaced apart from each other in the second axis direction (Y-axis direction). At the same time, rotation of the rotating plate 200 with respect to the housing 110 about the first axis (X-axis) as a rotation axis may be limited.

Additionally, when the rotating plate 200 is relatively rotated with respect to the housing 110 with respect to the second axis (Y-axis), the reflective module 300 may be rotated relative to the second axis (Y-axis) together with the rotating plate 200 as a rotation axis. For example, the reflection module 300 may be relatively rotated with respect to the rotating plate 200 with respect to the second axis (Y-axis) as the axis of rotation, which is limited, but the reflective module 300 being rotated relative to the housing 110 together with the rotating plate 200 about the second axis (Y-axis) as the axis of rotation is not limited.

According to an example, the camera module 1000 may include a driving unit to rotate the reflective module 300 based on a first axis (X-axis) and a second axis (Y-axis) perpendicular to the optical axis (Z-axis) as described above. Specifically, the camera module 1000 may include a first driving unit 810 that rotates the reflective module 300 with a first axis (X-axis) as a rotation axis, and a second driving unit 830 that rotates the reflective module 300 with a second axis (Y-axis) as a rotation axis. The first driving unit 810 and the second driving unit 830 may be hand shake correction units, and may be a VCM actuator that uses the electromagnetic force between the magnet and the coil as the driving force.

The first driving unit 810 may include a first magnet 811 and a first coil 813.

Referring to FIG. 10, in an example, the first magnet 811 may be disposed on the reflective module 300, and in an example, the first magnet 811 may be disposed on a sidewall of the holder 330. Since the first magnet 811 may be disposed on the rotating reflective module 300, it may be a movable member.

The first coil 813 may be disposed in the housing 110, to face the first magnet 811 in a direction perpendicular to the optical axis direction (Z-axis direction), and in the second axis direction (Y-axis direction) based on the drawing. Specifically, the housing 110 may include a through-hole 113 disposed on the side, and the first coil 813 may be disposed in the housing 110 as the substrate 170 is coupled to the housing 110 while being mounted on the substrate 170. The first coil 813 may face the first magnet 811 in the second axis direction (Y-axis direction) through the through-hole 113. Since the first coil 813 is disposed in the housing 110, it may be a fixing member.

The first magnet 811 may include a plurality of magnets, and the plurality of magnets may be dividedly disposed on both sidewalls of the holder 330. Additionally, the first coil 813 may include a plurality of coils to correspond to the first magnet 811.

On the other hand, in one or more examples, the first magnet 811 may be a moving member disposed on the reflective module 300, an example in which the first coil 813 is a fixing member disposed in the housing 110 will be described, and conversely, the first magnet 811 becomes a fixing member disposed in the housing 110, and an example in which the first coil 813 is a movable member disposed on the reflective module 300 is also possible.

The first magnet 811 may have a length in the first axis direction (X-axis direction). Additionally, the first magnet 811 may be in a form in which the surface facing the first coil 813 is magnetized in the optical axis direction (Z-axis direction). For example, the first magnet 811 may have a first polarity 811a and a second polarity 811b along the optical axis direction (Z-axis direction), and a neutral zone 811c may be provided between the first polarity 811a and the second polarity 811b. The first polarity 811a may be an N pole or an S pole, and the second polarity 811b may conversely be an S pole or an N pole opposite to the first polarity 811a. The first polarity 811a, the second polarity 811b, and the neutral region 811c of the first magnet 811 may be elongated in the first axis direction (X-axis direction).

The first magnet 811 and the first coil 813 may generate a driving force in a direction perpendicular to a direction facing each other. For example, the first magnet 811 and the first coil 813 may generate a driving force in an optical axis direction (Z-axis direction) perpendicular to a second axis direction (Y-axis direction) facing each other. Based on the driving force of the first magnet 811 and the first coil 813, the reflective module 300 may be rotated left and right with the first axis (X-axis) as the rotation axis.

On the other hand, the holder 330 may have a form in which both side walls protrude in the optical axis direction (Z-axis direction) toward the rotating plate 200 to surround the rotating plate 200, and the first magnet 811 may be disposed on both sidewalls of the holder 330. In this example, the neutral region 811c of the first magnet 811 may be located on the same line as the center of the first ball member (B1) and the second axis direction (Y-axis direction), or may be disposed in front of the light path rather than the center of the first ball member B1. Therefore, the reflective module 300 having relatively smaller driving force may be rotated.

The second driving unit 830 may include a second magnet 831 and a second coil 833.

The second magnet 831 may be disposed on the reflective module 300,

In an example, the second magnet 831 may be disposed on a sidewall of the holder 330. Since the second magnet 831 may be disposed on the rotating reflective module 300, it may be a movable member.

The second coil 833 may be disposed in the housing 110 to face the second magnet 831 in a direction perpendicular to the optical axis direction (Z-axis direction), and in the second axis direction (Y-axis direction) based on the drawing. Specifically, the housing 110 may include a through-hole 113 on the side, and the second coil 833 may be disposed in the housing 110 as the substrate 170 is coupled to the housing 110 while being mounted on the substrate 170. The second coil 833 may face the second magnet 831 in the second axis direction (Y-axis direction) through the through-hole 113. Since the second coil 833 may be disposed in the housing 110, it may be a fixing member.

The first magnet 811 may include a plurality of magnets, and the plurality of magnets may be dividedly disposed on both sidewalls of the holder 330. Additionally, the first coil 813 may include a plurality of coils to correspond to the first magnet 811.

On the other hand, in the one or more examples, the second magnet 831 may be a moving member disposed on the reflective module 300, and an example in which the second coil 833 is a fixing member disposed on the housing 110 will be described. Conversely, the second magnet 831 becomes a fixing member disposed in the housing 110, and an example in which the second coil 833 is a movable member disposed on the reflective module 300 is also possible.

The second magnet 831 may have a length in the first axis direction (X-axis direction). Additionally, the second magnet 831 may have a form in which a surface facing the second coil 833 is magnetized in the first axis direction (X-axis direction). For example, the second magnet 831 may have a first polarity 831a, a second polarity 831b, and a first polarity 831a along the first axis direction (X-axis direction), and a neutral zone 831c may be provided between the first polarity 811a and the second polarity 811b and between the second polarity 831b and the first polarity 831a. The first polarity 811a may be an N pole or an S pole, and the second polarity 811b may be an S pole or an N pole opposite to the first polarity 811a. Additionally, the neutral region 831c provided between the first polarity 811a and the second polarity 811b is the first neutral region, and the neutral region 831c provided between the second polarity 811b and the first polarity 811a may be the second neutral region. The first polarity 811a, the second polarity 811b, and the neutral region 811c of the second magnet 831 may be elongated in the optical axis direction (Z-axis direction).

The second magnet 831 and the second coil 833 may generate a driving force in a direction perpendicular to a direction facing each other. In this example, the second magnet 831 and the second coil 833 may generate a driving force in a direction perpendicular to the direction of the driving force generated by the first magnet 811 and the first coil 813. For example, the second magnet 831 and the second coil 833 may generate a driving force in a first axial direction (X-axis direction) perpendicular to a second axial direction (Y-axis direction) facing each other. Based on the driving force of the second magnet 831 and the second coil 833, the reflective module 300 may be rotated up and down using the second axis (Y-axis) as a rotation axis.

On the other hand, the second magnet 831 may be disposed further back than the first magnet 811 based on the optical path. For example, the second magnet 831 may be disposed closer to the lens module 400 than the first magnet 811.

Accordingly, the separation distance in the optical axis direction (Z-axis direction) between the center of the second ball member B2 and the neutral region 831c of the second magnet 831 may be greater than the separation distance between the center of the second ball member B2 and the neutral region 811c of the first magnet 811 in the optical axis direction (Z-axis direction). Therefore, the reflective module 300 with a smaller driving force may be rotated.

According to an example, the second magnet 831 is a driving magnet to rotate the reflective module 300 by forming an electromagnetic force with the second coil 833, and may be a sensing magnet that senses the position of the reflective module 300 together with a position sensor to be described later. For example, the second magnet 831 may have a form in which a driving magnet and a sensing magnet are integrally formed, and accordingly, the second magnet 831 may further include a neutral region 831c and a first polarity 831a in the first axis (X-axis direction) as described above.

A driving magnet may be used to sense the position of the reflective module 300, but when the position of the reflective module 300 is sensed through the sensing magnet as described above, the position of the reflective module 300 may be sensed with high sensitivity.

For example, in the structure of the second magnet 831, the first polarity 831a and the second polarity 831b provided on the side of the cover 130 in the first axial direction (X-axis direction) may be implemented as a driving magnet, and the first polarity 831a and the second polarity 831b provided on the housing 110 side in the first axial direction (X-axis direction) may be implemented as a sensing magnet. Therefore, since the position sensing of the reflective module 300 may be performed at a position relatively far away in the first axis direction (X-axis direction) from the part where the driving force of the second magnet 831 is generated (for example, a position with a lot of movement), sensing sensitivity may be improved as compared to when a driving magnet is used as a sensing magnet.

Additionally, according to an example, the driving force generated by the second magnet 831 and the second coil 833 rotates the reflective module 300 with the second axis (Y-axis) as the rotation axis, and as the second magnet 831 is provided with a driving magnet and a sensing magnet integrated structure, thereby more accurately sensing the position of the reflective module 300 in the first axis direction (X-axis direction).

Furthermore, according to an example, as the second magnet 831 is provided in an integrated structure of a driving magnet and a sensing magnet, the thickness of the camera module 1000 in the first axis direction (X-axis direction) may be reduced.

According to an example, the camera module 1000 may use a closed-loop control method to detect and feed back the position of the reflective module 300. Accordingly, the camera module 1000 may include a first position sensor 815 and a second position sensor 835 to detect the position of the reflective module 300.

In a non-limiting example, the first position sensor 815 and the second position sensor 835 may be tunnel magnetoresistance (TMR) sensors.

The first position sensor 815 and the second position sensor 835 may be disposed in the housing 110. Specifically, the housing 110 may include a through-hole 113 on the side, and the first position sensor 815 and the second position sensor 835 may be mounted on the substrate 170 together with the first coil 813 and the second coil 833 and the substrate 170 may be coupled to the housing 110, to be disposed in the housing 110.

The first position sensor 815 and the second position sensor 835 may be disposed to face the first magnet 811 and the second magnet 831 through the through-hole 113, respectively. For example, the first position sensor 815 may be disposed to face the neutral region 811c of the first magnet 811, and the second position sensor 835 may be disposed to face the neutral region 831c of the second magnet 831. In an example, the second position sensor 835 may be disposed to face the second neutral region 831c provided on the side of the housing 110 from among the two neutral regions 831c of the second magnet 831 provided in the first axial direction (X-axis direction). Details related thereto will be described later.

Additionally, the first position sensor 815 and the second position sensor 835 may be provided in numbers corresponding to the plurality of magnets constituting the first magnet 810 and the second magnet 830, and may be placed facing each magnet.

On the other hand, the lens module 400 may be disposed at the rear of the reflective module 300 in the internal space of the housing 110. According to an example, the camera module 1000 may adjust the focus during an image capture process by moving the lens module 400 in the optical axis direction (Z-axis direction).

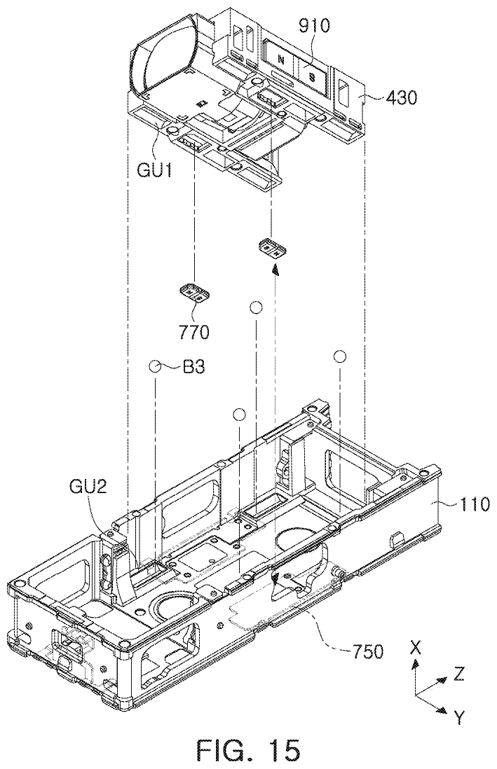

FIG. 15 is a diagram illustrating a portion in which an attractive force is formed between a housing of a camera module and a lens module, in accordance with one or more embodiments.

The lens module 400 may be supported on the inner surface of the housing 110 in an example in which it is disposed in the internal space of the housing 110. For example, as illustrated in FIG. 15, the lens module 400 may be pulled toward the inner surface of the housing 110 in the first axis direction (X-axis direction) perpendicular to the optical axis direction (Z-axis direction).

Accordingly, magnetic materials may be disposed on surfaces facing each other in the first axis direction (X-axis direction) of the housing 110 and the lens module 400. Specifically, the third magnetic body may be disposed in the housing 110, a fourth magnetic material may be disposed on the carrier 430 of the lens module 400, and at least one of the third magnetic material and the fourth magnetic material may be a pulling magnet.

For example, the third magnetic material disposed in the housing 110 may be a pulling yoke (hereinafter, a second pulling yoke) 750, and the fourth magnetic material disposed on the carrier 430 may be a pulling magnet (hereinafter, referred to as a second pulling magnet) 770.

The second pulling yoke 750 and the second pulling magnet 770 may be disposed to face each other in the first axial direction (X-axis direction) to generate an attractive force in the first axial direction (X-axis direction). Accordingly, the lens module 400 may be pulled toward the inner surface of the housing 110 in the first axial direction (X-axis direction).

On the contrary, the third magnetic body disposed in the housing 110 may be the second pulling magnet 770, the fourth magnetic body disposed on the carrier 430 may be a second pulling yoke 750, and an example in which both the third magnetic material and the fourth magnetic material disposed in the housing 110 and the carrier 430 are the second pulling magnets 770 is also possible.

For example, the second pulling yoke 750 may be provided in the form of a thin plate.

On the other hand, since the second pulling magnet 770 may be disposed adjacent to the inner surface of the housing 110 such that the lens module 400 is supported on the inner surface of the housing 110, in the example in which the magnetic field is formed over a wide area, a portion of the magnetic field may leak to the outside of the camera module 1000. Accordingly, the second pulling magnet 770, in accordance with one or more embodiments, may be provided in a form that is polarized in the longitudinal direction and the width direction as illustrated in FIG. 10, and magnetic field leakage may be significantly reduced.

A third ball member B3 may be disposed between the lens module 400 and the housing 110. Specifically, the third ball member B3 may be disposed between the carrier 430 and the housing 110. The third ball member B3 may include a plurality of ball members spaced apart along the optical axis (Z-axis), which is the longitudinal direction of the carrier 430, and a plurality of ball members spaced apart in the second axis (Y-axis) that is the width direction of the carrier 430. The third ball member B3 may guide the movement of the lens module 400 in the optical axis direction (Z-axis direction) with respect to the housing 110.

Guide grooves in which the third ball member B3 is accommodated may be provided on surfaces of the carrier 430 and the housing 110 facing each other in the first axial direction (X-axis direction). For example, the carrier 430 may be provided with a first guide groove (GU1) on the surface facing the housing 110 and the first axis direction (X-axis direction), and the housing 110 may include a second guide groove GU2 on a surface facing the carrier 430 in the first axial direction (X-axis direction).

The first guide groove GU1 and the second guide groove GU2 may include a plurality of receiving grooves spaced apart along the optical axis (Z-axis) and the second axis (Y-axis). Additionally, the first guide groove (GU1) and the second guide groove (GU2) may be formed in a shape having a length in the optical axis direction (Z-axis direction), to guide the movement of the lens module 400 in the optical axis direction (Z-axis direction).

The third ball member (B3) may be disposed between the first guide groove (GU1) and the second guide groove (GU2), and may be stably disposed without departing from the first guide groove GU1 and the second guide groove GU2 by the attractive force between the second pulling yoke 750 and the second pulling magnet 770.

The third ball member B3 may roll along the first guide groove GU1 and the second guide groove GU2, in an example when disposed between the first guide groove (GU1) and the second guide groove (GU2). Therefore, when the driving force is generated in the optical axis direction (Z-axis direction) by the third driving unit 900 to be described later, the lens module 400 may be moved in the optical axis direction (Z-axis direction) based on the third ball member B3.

According to an example, the camera module 1000 may include a third driving unit 900 to move the lens module 400 in the optical axis direction (Z-axis) as described above. The third driving unit 900 may be an autofocus adjustment unit, and may be a VCM actuator that uses the electromagnetic force between the magnet and the coil as the driving force.

The third driving unit 900 may include a third magnet 910 and a third coil 930.

The third magnet 910 may be disposed on the lens module 400, and for example, the third magnet 910 may be disposed on a side surface of the carrier 430. The third magnet 910 may be disposed on the moving carrier 430, and may thus be a moving member.

The third coil 930 may be disposed in the housing 110 to face the third magnet 910 in a direction perpendicular to the optical axis direction (Z-axis direction) and in a second axis direction (Y-axis direction) based on the drawing. Specifically, the housing 110 may include a through-hole 115 in the side, and the third coil 930 may be disposed in the housing 110 as the substrate 170 is coupled to the housing 110 while being mounted on the substrate 170. The third coil 930 may face the third magnet 910 in the second axis direction (Y-axis direction) through the through-hole 115. The third coil 930 may be disposed in the housing 110, and may thus be a fixing member.

The third magnet 910 may include a plurality of magnets, and the plurality of magnets may be dividedly disposed on both sidewalls of the carrier 430. Additionally, the third coil 930 may include a plurality of coils to correspond to the third magnet 930.

On the other hand, in the one or more examples, the third magnet 910 may be a moving member disposed on the lens module 400, and an example in which the third coil 930 is a fixing member disposed on the housing 110 will be described. Conversely, the third magnet 910 may be implemented as a fixing member disposed in the housing 110, and an example in which the third coil 930 is a movable member disposed on the reflective module 300 is also possible.

The third magnet 910 may have a length in the optical axis direction (Z-axis direction). Additionally, the third magnet 910 may be in a form in which the surface facing the third coil 930 is magnetized in the optical axis direction (Z-axis direction). For example, the third magnet 910 may have a first polarity 910a and a second polarity 910b along the optical axis direction (Z-axis direction), and a neutral zone 910c may be provided between the first polarity 910a and the second polarity 910b. The first polarity 910a may be an N pole or an S pole, and the second polarity 910b may be an S pole or an N pole opposite to the first polarity 910a. The first polarity 910a and the second polarity 910b of the third magnet 910 are elongated in the optical axis direction (Z-axis direction), and the neutral region 910c may be elongated in the first axis direction (X-axis direction).

The third magnet 910 and the third coil 930 may generate a driving force in a direction perpendicular to a direction facing each other. For example, the third magnet 910 and the third coil 930 may generate a driving force in an optical axis direction (Z-axis direction) perpendicular to a second axis direction (Y-axis direction) facing each other. The lens module 400 may be moved in the optical axis direction (Z-axis direction) by the driving force of the third magnet 910 and the third coil 930.

According to an example, the camera module 1000 may use a closed-loop control method to detect and feed back the position of the lens module 400. Accordingly, the camera module 1000 may include a third position sensor 950 to detect the position of the lens module 400.

For example, the third position sensor 950 may be a Hall sensor.

The third position sensor 950 may be disposed in the housing 110. Specifically, the housing 110 may include a through-hole 115 in the side, and the third position sensor 950 may be disposed on the housing 110 as the substrate 170 is coupled to the housing 110 while being mounted on the substrate 170 together with the third coil 930. The third position sensor 950 may be disposed to face the lens module 400 through the through-hole 115. For example, the third position sensor 950 may be disposed to face one surface of the carrier 430 in the second axis direction (Y-axis direction).

Additionally, the third position sensor 950 may be provided as one or may be provided in a number corresponding to a plurality of magnets constituting the third magnet 910 and disposed to face each magnet.

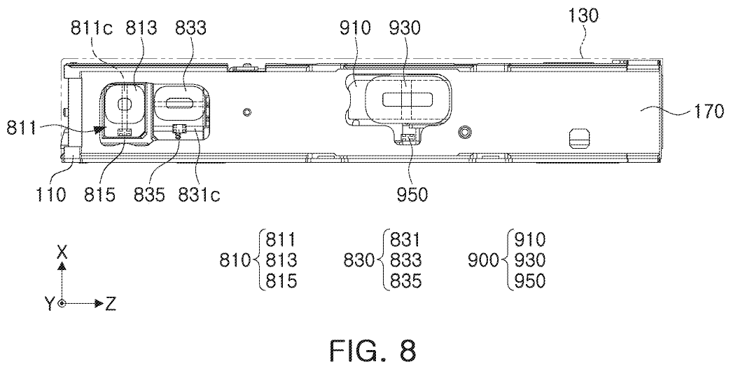

FIG. 8 is a side view of the housing in an example in which the substrate illustrating the arrangement relationship of the driving unit of the camera module according to an example is removed.

According to an example, in the camera module 1000, to reduce the leakage magnetic flux, the first to third driving units 810, 830, and 900 may be disposed closer to the cover 130 than the housing 110 in a direction perpendicular to the optical axis direction. Since the cover 130 is formed of a metal material that may shield electromagnetic waves, a magnetic field formed outside the camera module 1000 may be shielded by the cover 130, by causing the driving force, for example, the electromagnetic force between the magnet and the coil, to occur on the cover 130 side.

Referring to FIG. 8, at least a plurality of coils 813, 833, and 930 are disposed in the first axis direction (X-axis direction) perpendicular to the optical axis direction (Z-axis direction) of the housing 110 rather than the bottom surface of the housing 110. It may be disposed to be closer to one surface of the cover 130 facing the bottom surface. The receiving surface of the housing 110 and one surface of the cover 130 have a first axis direction (X-axis direction) in a first axis and a second axis direction (X-axis and Y-axis direction) perpendicular to the optical axis direction (Z-axis direction), and therefore, in the one or more examples, the disclosure that the plurality of coils 813, 833, and 930 are disposed closer to the cover 130 side than the housing 110 in a direction perpendicular to the optical axis direction refers to being disposed closer to the cover 130 than to the housing 110 in the first axial direction (X-axis direction).

Specifically, the first magnet 811 of the first driving unit 810 and the second magnet 831 of the second driving unit 830 may have a length in the first axial direction (X-axis direction), and thus, may not be disposed adjacent to any one of the housing 110 and the cover 130 in the first axial direction (X-axis direction), and the longitudinal center of the first magnet 810 and the second magnet 830 may be disposed to approximately coincide with a center between the housing 110 and the cover 130 in the first axis direction (X-axis direction). However, since the first coil 813 of the first driving unit 810 and the second coil 833 of the second driving unit 830 have a length in the optical axis direction (Z-axis direction), to generate a driving force from the cover 130 side, the first coil 813 and the second coil 833 should be disposed closer to the cover 130 than to the housing 110 in the first axial direction (X-axis direction).

For example, the area where the first magnet 811 and the first coil 813 face each other and the area where the second magnet 831 and the second coil 833 face each other may be disposed to be closer to the cover 130 than the housing 110 in the first axial direction (X-axis direction).

Accordingly, the first position sensor 815 and the second position sensor 835 may be disposed to be closer to the bottom surface of the housing 110 than the cover 130 in the first axis direction (X-axis direction). Specifically, the first position sensor 815 and the second position sensor 835 may be disposed adjacent to the bottom surface of the housing 110 in the first axial direction (X-axis direction), and in the second axis direction (Y-axis direction), the neutral regions 811c and 831c of the first magnet 811 and the second magnet 831 may be disposed to face each other.

In this example, since the first magnet 811 has one neutral region 811c having a length in the first axial direction (X-axis direction), the first position sensor 815 may be disposed to face the neutral region 811c on a side adjacent to the bottom surface of the housing 110 in the first axis direction (X-axis direction). On the other hand, since the second magnet 831 has two neutral regions 831c having a length in the optical axis direction (Z-axis direction) along the first axis direction (X-axis direction) as described above, the second position sensor 835 may be disposed to face the second neutral region 831c provided on the housing 110 side in the first axial direction (X-axis direction) among the two neutral regions 831c.

On the other hand, in the example of the third driving unit 900, since both the third magnet 910 and the third coil 930 may have a length in the optical axis direction (Z-axis direction), the third magnet 910 and the third coil 930 may be disposed to be closer to the cover 130 than the bottom surface of the housing 110 in the first axis direction (X-axis direction).

As described above, the reflective module 300 and the camera module 1000 including the same according to an example leak to the outside as the driving units 810, 830 and 900 are disposed on the cover 130 side, and accordingly, the resulting magnetic field may be significantly reduced. Additionally, the reflective module 300 and the lens module 400 are magnetic materials provided to be supported on the inner surface of the housing 110 by providing pulling magnets 730 and 770 in the form of magnetization in the longitudinal and width directions. The above-described leakage flux reduction effect may be significantly increased.

As set forth above, in the camera module according to an example, leakage magnetic flux may be reduced, and accordingly, magnetic field interference may be significantly reduced.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A camera module, comprising:
a housing configured to have an internal space;
a lens module disposed in the internal space, and comprising a plurality of lenses arranged in an optical axis direction;
a reflective module, disposed in front of the lens module, and comprising a reflective member and a holder provided with the reflective member mounted thereon;
a driving unit configured to move the lens module in the optical axis direction or configured to rotate the reflective module in a direction, perpendicular to the optical axis direction, as a rotation axis; and
a cover coupled to the housing,
wherein the driving unit comprises a plurality of magnets, and a plurality of coils disposed in the housing to face the plurality of magnets, respectively, and
wherein the plurality of coils are disposed to be closer to a first surface of the cover facing a bottom surface of the housing than to the bottom surface of the housing in a direction, perpendicular to the optical axis direction.

2. The camera module of claim 1, further comprising a plurality of position sensors configured to detect positions of the lens module and positions of the reflective module,
wherein the plurality of position sensors are disposed to be closer to the bottom surface of the housing than to the first surface of the cover facing the bottom surface of the housing in the direction, perpendicular to the optical axis direction.

3. The camera module of claim 2, wherein the driving unit comprises:
a first driving unit comprising a first magnet and a first coil, and configured to rotate the reflective module with respect to the housing, by implementing a first axis, perpendicular to the optical axis, as a rotation axis;
a second driving unit comprising a second magnet and a second coil, and configured to rotate the reflective module with respect to the housing, by implementing a second axis, perpendicular to the optical axis, as a rotation axis; and
a third driving unit comprising a third magnet and a third coil, and configured to move the lens module in the optical axis direction with respect to the housing.

4. The camera module of claim 3, wherein the first magnet and the second magnet have a length in the first axis direction, and the third magnet has a length in the optical axis direction.

5. The camera module of claim 3, wherein the third magnet is disposed to be closer to the cover, on the first surface of the cover facing the bottom surface of the housing, than the bottom surface of the housing, in a direction, perpendicular to the optical axis direction.

6. The camera module of claim 3, wherein the plurality of position sensors comprise:
a first position sensor configured to face the first magnet;
a second position sensor configured to face the second magnet; and
a third position sensor configured to face the lens module.

7. The camera module of claim 6, wherein a surface of the first magnet that faces the first coil is provided as a first polarity, a neutral region and a second polarity sequentially in the optical axis direction.

8. The camera module of claim 7, wherein the first position sensor is configured to face the neutral region.

9. The camera module of claim 6, wherein a surface of the second magnet that faces the second coil is provided as a first polarity, a first neutral region, a second polarity, a second neutral region, and a first polarity sequentially in the first axis direction.

10. The camera module of claim 9, wherein the second position sensor is configured to face the second neutral region.

11. The camera module of claim 1, wherein the cover is formed of a metal material that shields electromagnetic waves.

12. The camera module of claim 1, wherein at least one of the housing and the reflective module comprises a first pulling magnet on surfaces that face each other in the optical axis direction, such that an attractive force acts between the housing and the reflective module in the optical axis direction.

13. The camera module of claim 12, wherein the first pulling magnet is polarized in a longitudinal direction and a width direction.

14. The camera module of claim 1, wherein at least one of the housing and the lens module comprises a second pulling magnet on surfaces that face each other in a direction, perpendicular to the optical axis direction, such that an attractive force acts between the housing and the lens module in a direction, perpendicular to the optical axis direction.

15. The camera module of claim 14, wherein the second pulling magnet is polarized in a longitudinal direction and a width direction.

16. A camera module, comprising:
a housing having an open upper portion;
a lens module and a reflective module disposed in the housing, and configured to have at least one magnet mounted on a side thereof; and
a substrate disposed on a side surface of the housing and configured to have a plurality of coils mounted on a surface that faces an inside of the housing,
wherein the reflective module is configured to rotate with a first axis and a second axis, perpendicular to an optical axis direction, as rotation axes, and
wherein the plurality of magnets and the plurality of coils are disposed to face each other in a position higher than a point where the first axis and the second axis intersect.
